(19) United States
(12) Patent Application Publication
(10) Pub. No.: US 2015/0060761 A1
(43) Pub. Date: Mar. 5, 2015

(54) NITRIDE SEMICONDUCTOR LIGHT EMITTING DEVICE

(71) Applicant: KABUSHIKI KAISHA TOSHIBA, Tokyo (JP)

(72) Inventor: Akira TANAKA, Yokohama (JP)

(73) Assignee: KABUSHIKI KAISHA TOSHIBA, Tokyo (JP)

(21) Appl. No.: 14/189,243

(22) Filed: Feb. 25, 2014

(30) Foreign Application Priority Data
Aug. 30, 2013 (JP) 2013-179836

(51) Int. Cl. H01L 33/38; H01L 33/32; H01L 33/06

(52) U.S. Cl. CPC H01L 33/382; H01L 33/06; H01L 33/32
USPC 257/13

(57) ABSTRACT

A nitride semiconductor light emitting device includes a first layer of a first-conductivity type, first and second protrusions each disposed on a first side of the first layer and extending from the first layer in a first direction and spaced apart from each other in a second direction perpendicular to the first direction, a first electrode disposed on the first side of the first layer and between the first and second protrusions, a phosphor layer disposed on a second side of the first layer that is opposite the first side, and a second electrode disposed on each of the first and second protrusions on a side opposite the first layer. The first and second protrusions each includes a second layer having a second-conductivity type, and a light emitting layer disposed between the first layer and the second layer.

### CROSS-REFERENCE TO RELATED APPLICATION

This application is based upon and claims the benefit of priority from Japanese Patent Application No. 2013-179836, filed Aug. 30, 2013, the entire contents of which are incorporated herein by reference.

### FIELD

Embodiments described herein relate generally to a nitride semiconductor light emitting device.

### BACKGROUND

Nitride semiconductor light emitting devices are widely used in illuminating devices, video displays, signals transmission, and so on. In these applications, semiconductor light emitting devices having low operating voltages and high optical outputs are generally preferred.

In nitride semiconductor light emitting devices, it is common to provide a p-side electrode and an n-side electrode on one side of a semiconductor laminate in which a step portion is formed, and then use the other side of the laminate as a light emitting surface.

When charge carriers are intensively injected into a narrow peripheral area of a light emitting layer close to the p-side electrode and the n-side electrode, Auger non-radiative recombination and carrier overflow increase. For this reason, the luminous efficiency decreases, and thus high optical output cannot be obtained, and the operating voltage also becomes higher.

Further, when light emitting areas are concentrated in the peripheral area of the laminate, the ratio of light which is emitted from the side surface of the chip increases. For this reason, chromaticity is different between the central portion and peripheral portion of the chip, and color irregularity becomes likely to occur due to optical path length differences.

### DESCRIPTION OF THE DRAWINGS

FIG. 1A is a schematic cross-sectional view illustrating a nitride semiconductor light emitting device according to a first embodiment, and FIG. 1B is a schematic plan view taken along a line A-A of FIG. 1A.

FIGS. 2A to 2D are schematic views illustrating a process of manufacturing the nitride semiconductor light emitting device according to the first embodiment.

FIG. 3A is a schematic cross-sectional view illustrating a nitride semiconductor light emitting device according to a comparative example, and FIG. 3B is a schematic plan view taken along a line A-A of FIG. 3A.

FIG. 4A is a graph illustrating dependence of optical output on current, and FIG. 4B is a graph for comparing light distribution patterns.

FIG. 5A is a schematic cross-sectional view illustrating a nitride semiconductor light emitting device according to a second embodiment, and FIG. 5B is a schematic plan view taken along a line A-A of FIG. 5A.

FIG. 6 is a graph illustrating the optical output of the nitride semiconductor light emitting device according to the second embodiment.

FIG. 7A is a schematic cross-sectional view illustrating a nitride semiconductor light emitting device according to a third embodiment, and FIG. 7B is a schematic plan view taken along a line A-A of FIG. 7A.

FIG. 8 is a schematic cross-sectional view illustrating a nitride semiconductor light emitting device according to a fourth embodiment.

### DETAILED DESCRIPTION

Embodiments provide a nitride semiconductor light emitting device having less color irregularity and higher optical output.

In general, according to one embodiment, a nitride semiconductor light emitting device includes a first layer of a first-conductivity type layer, first and second protrusions each disposed on a first side of the first layer and extending from the first layer in a first direction and spaced apart from each other in a second direction perpendicular to the first direction, a first electrode disposed on the first side of the first layer and between the first and second protrusions, a phosphor layer disposed on a second side of the first layer that is opposite the first side, and a second electrode disposed on each of the first and second protrusions on a side opposite the first layer. The first and second protrusions each includes a second layer having a second-conductivity type, and a light emitting layer disposed between the first layer and the second layer.

Hereinafter, embodiments of the present disclosure will be described with reference to the accompanying drawings.

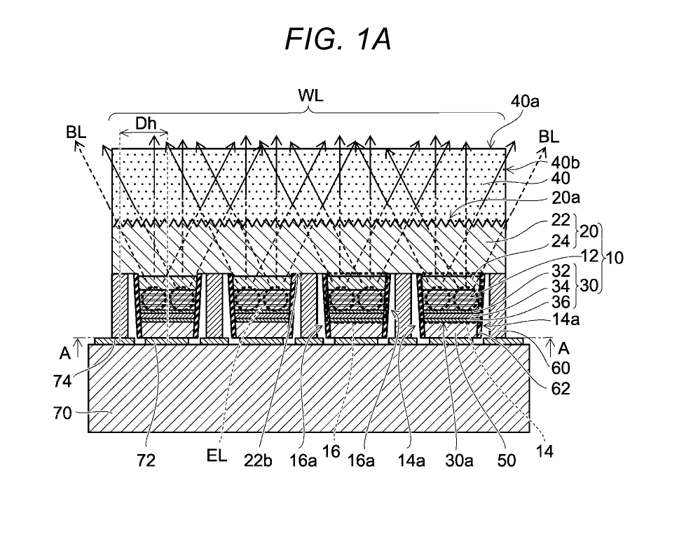

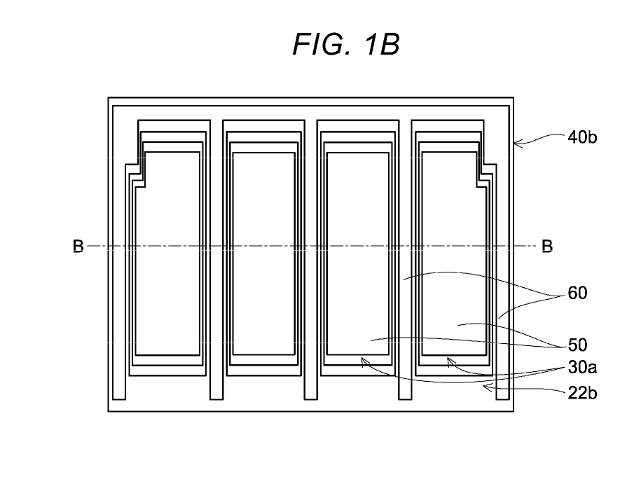

FIG. 1A is a schematic cross-sectional view illustrating a nitride semiconductor light emitting device according to a first embodiment, and FIG. 1B is a schematic plan view illustrating the laminate side as seen along a line A-A of FIG. 1A.

The nitride semiconductor light emitting device includes a laminate 10, a first electrode 60, a second electrode 50, and a phosphor layer 40. Further, FIG. 1A is a schematic cross-sectional view taken along a line B-B of FIG. 1B.

The laminate 10 includes a first layer 20 including a first-conductivity type layer 22 (a doped layer), a second layer 30 including a second-conductivity type layer, and a light emitting layer 12 is provided between the first layer 20 and the second layer 30 and contains a nitride semiconductor. The laminate 10 includes at least two ridge portions having step portions formed from the surface 30a of the second layer opposite to the light emitting layer 12 up to the first-conductivity type layer 22 of the first layer 20.

The first electrode 60 is formed on a surface 22b (base surface) between a first ridge portion 14 and a second ridge portion 16. As depicted in FIG. 1B, the portions of first electrode 60 between ridge portions are connected to each other by another portion of first electrode 60 that is not directly between the ridge portions and extends in a direction parallel to a direction crossing the ridge portions formed on the first-conductivity type layer 22. The portion of first electrode 60 formed between first ridge portion 14 and second ridge portion 16 is formed so as to be adjacent to a step portion 14a formed in the longitudinal direction (e.g., the top-bottom page direction of FIG. 1B) of the first ridge portion 14 and a step portion 16a formed in the longitudinal direction of the second ridge portion 16. Further, the second electrode 50 is formed on the surface 30a of the second layer 30. In FIG. 1B, the first electrode 60 has five stripe portions (portions between ridge portions), and is open toward one direction (downward in FIG. 1B); however, the tip portions of the stripe portions may also be connected to each other with an additional portion of electrode 60, or similar conductive material (s).

The phosphor layer 40 is formed on the surface 20a of the first layer 20 opposite to the light emitting layer 12—that is, the surface 20a is on the layer face of first layer 20 that is not in contact with the light emitting layer 12. The phosphor layer 40 has a side surface 40b provided outside (that is, beyond the outside edges) of the first ridge portion 14 and the second ridge portion 16. Thus, in FIG. 1B, the outside edge of phosphor layer 40 (which is the projection of the side surface 40b on to the page plane of FIG. 1B) is beyond the outside edges of the depicted ridge portions. Although at least two ridge portions are provided in the present embodiment, in FIGS. 1A and 1B, a case where four ridge portions are provided is shown. The phosphor layer 40 can be formed by mixing Yttrium-Aluminum-Garnet (YAG) phosphor particles or the like in transparent resin liquid, applying the mixture, and performing thermal curing or the like.

The surface of the phosphor layer 40 opposite to the laminate 10 becomes a light emitting surface 40a for light from the light emitting layer 12. The phosphor layer 40 can serve to absorb at least some portion of emitted light from light emitting layer and then emit light at a wavelength longer than the wavelength of the emitted light from the light emitting layer. For example, in a case where the emitted light from light emitting layer 12 is blue light, and when the phosphor layer 40 contains a yellow phosphor, the blue light is converted to a yellow light that can be mixed to form white light. Furthermore, various phosphors can be included in phosphor layer 40 as required by various potential applications, such that the phosphor layer 40 can contain a green (to yellow) phosphor and a red phosphor, such that blue light emitted light from the light emitting layer 12 can be mixed with green (to yellow) light and red light, provided by the various included phosphors, to form white light.

In the first embodiment, a horizontal distance Dh from the center of the light emitting layer 12 to the center of a corresponding first electrode 60 can be decreased as the number of ridge portions increases. Therefore, it is possible to provide an approximately uniform carrier density distribution inside the light emitting layer 12. Further, when the planar shape of each of at least two ridge portions is set to a rectangular shape, it is possible to make the horizontal distance Dh along the shorter-side direction of the corresponding rectangular ridge portion shorter than that in a case where the planar shape is a square shape having the same area. Therefore, a luminous area EL (shown by a dotted line) of the inside of the light emitting layer 12 uniformly broadens, and the ratio of blue light BL to longer wavelength light (e.g., yellow light) emitted from the side surface 40b of the phosphor layer 40 decreases, and color irregularity is suppressed.

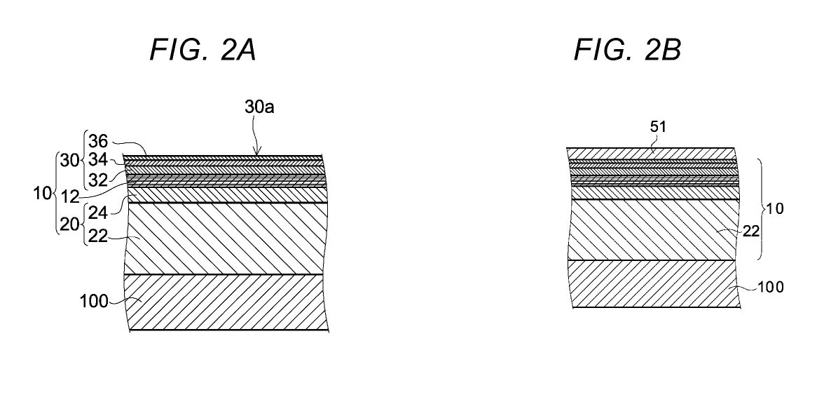

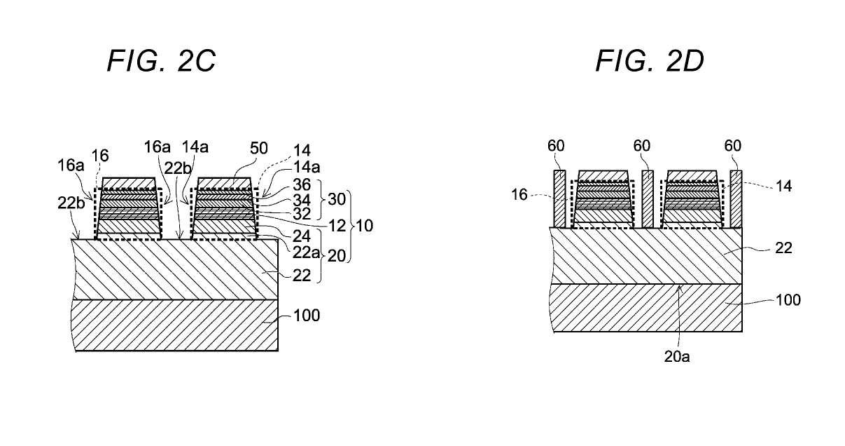

FIGS. 2A to 2D are schematic views illustrating a process of manufacturing the nitride semiconductor light emitting device according to the first embodiment. That is, FIG. 2A is a schematic cross-sectional view illustrating a laminate that has been formed on a substrate for crystal growth, FIG. 2B is a schematic cross-sectional view illustrating a structure in which a metal layer 51 has been formed on the surface of the laminate 10, FIG. 2C is a schematic cross-sectional view illustrating a structure in which ridge portions have been formed, and FIG. 2D is a schematic cross-sectional view illustrating a structure in which a first electrode 60 has been formed.

As shown in FIG. 2A, on a substrate 100 for crystal growth formed of sapphire, a semiconductor, or the like, a nitride semiconductor is crystallized by metal-organic chemical vapor deposition (MOCVD) or the like, whereby the laminate 10 is formed. The first layer 20 of the laminate 10 includes the first-conductivity type layer (doped layer) 22, an undoped superlattice layer 24, and the like. The first-conductivity type layer 22 may be composed of an n-type GaN cladding layer and have a donor concentration of 1×10¹⁹ cm⁻³ and a thickness of 4 μm. The undoped superlattice layer 24 may be formed by alternately stacking 30 pairs of well layers formed of InGaN/InGaN and having thicknesses of 1 nm and barrier layers having thicknesses of 3 nm.

The light emitting layer 12 of the laminate 10 may be composed of an InGaN/InGaN undoped multi-quantum well (MQW) structure. The MQW structure may be formed by alternately stacking three well layers having thicknesses of 3 nm and four barrier layers having thicknesses of 10 nm, that is the well layers are disposed between barrier layers.

The second layer 30 of the laminate 10 may be formed by sequentially stacking, in the following order: an overflow preventing layer 32 (having an acceptor concentration of 1×10²⁰ cm⁻ and a thickness of 5 nm) comprising p-type AlGaN, a cladding layer 34 (having an acceptor concentration of 1×10²⁰ cm⁻³ and a thickness of 100 nm) comprising p-type GaN, a contact layer (having an acceptor concentration of 1×10²⁰ cm⁻³ and a thickness of 5 nm) comprising p⁺-type GaN. The thickness of the laminate 10 can be set, for example, in a range of 200 nm to 600 nm.

As shown in FIG. 2B, a metal layer 51 to be the second electrode 50 is formed on the entire upper surface of the contact layer 36. Next, an upper portion of the laminate 10 and a portion of the metal layer 51 are removed by etching, such that the upper portion of the laminate 10 is formed in to at least two ridge portions (i.e., first ridge portion 14 and second ridge portion 16). As a result, the step portions 14a and 16a are formed from the contact layer 36 of the surface 30a of the second layer 30 to the base surface 22b of the first layer 20. The first and second ridge portions 14 and 16 each include a portion 22a of the first-conductivity type layer 22, the undoped superlattice layer 24, the light emitting layer 12, the overflow preventing layer 32, the cladding layer 34, and the contact layer 36. Further, the second electrode 50 is disposed on the contact layer 36.

Further, the first electrode 60 is disposed on the exposed base surface 22b of the exposed first-conductivity type layer 22. It may be preferable to provide the base surface 22b inside of the first-conductivity type layer 22 rather than at the interface between the undoped superlattice layer 24 and the first-conductivity type layer 22. The reason is that it is possible to reduce contact resistance between the first electrode 60 and the first-conductivity type layer 22. The width of one stripe portion of the first electrode 60 can be set, for example, within a range of 5 μm to 15 μm.

As shown in FIG. 1A, a support-substrate-side first electrode (first connection electrode) 74 and a support-substrate-side second electrode (second connection electrode) 72 are formed on the surface of an insulating support substrate 70. The first electrode 60 and the support-substrate-side first electrode (first connection electrode) 74 are bonded to each other, and the second electrode 50 and the support-substrate-side second electrode (second connection electrode) 72 are bonded to each other. Thereafter, the substrate 100 for crystal growth can be removed, and the surface 22a of the first-conductivity type layer 22 is roughened—that is surface irregularities are introduced in the surface 22a such that surface 22a is not optically flat. The roughening of surface 22a may be referred to as a “frost” processing or the formation of “a plurality of concave-convex structures.” The roughening makes serves to improve light-extraction efficiency. On the roughened surface 22a, the phosphor layer 40 is formed.

In some embodiments, the conductive types of the layers in laminate 10 may be reversed. In order to keep the mechanical strength as a light emitting device, it is typically preferable to set the thickness of the insulating support substrate 70 to a large value such as, for example, 50 μm to 400 μm.

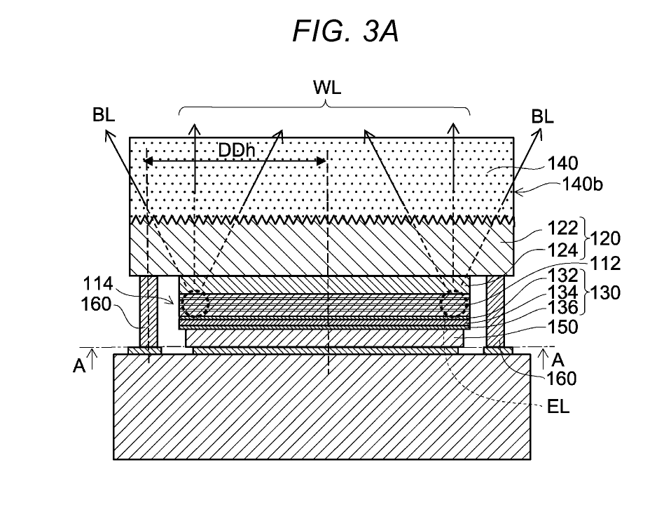

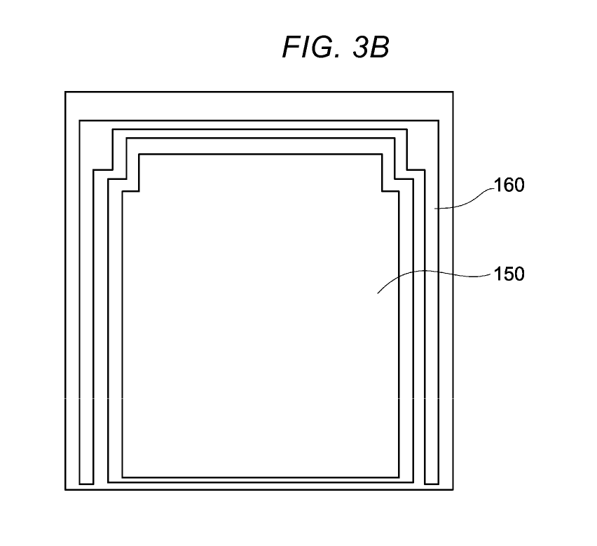

FIG. 3A is a schematic cross-sectional view illustrating a nitride semiconductor light emitting device according to a comparative example, and FIG. 3B is a schematic plan view illustrating the laminate side as seen along a line A-A of FIG. 3A.

The nitride semiconductor light emitting device has a laminate 110, a first electrode 160, a second electrode 150, and a phosphor layer 140.

The laminate 110 has a first layer 120 including a first-conductivity type layer 122, a second layer 130 including a second-conductivity type layer, and a light emitting layer 112 provided between the first layer 120 and the second layer 130, and contains a nitride semiconductor. The laminate 110 includes a single ridge portion 114 formed from the surface 130a of the second layer 130 opposite to the light emitting layer 112 up to the base surface of the first-conductivity type layer 122 of the first layer 120.

A horizontal distance DDh from the center of the light emitting layer 112 to the center of the first electrode 160 has a length of approximately ½ of the width of the chip (i.e., the depicted structure in FIG. 3A). Therefore, current is concentrated in a peripheral area (shown by a dotted line and labeled “EL”) close to the first electrode 160 and the second electrode 150. In this narrow peripheral area in which current is concentrated, the carrier density becomes high, and thus carrier overflow and Auger non-radiative recombination are likely to occur. Therefore, the luminous efficiency is likely to decrease. Further, at the central area of the ridge portion 114, since the carrier density decreases, the luminous efficiency is likely to decrease. A decrease in the luminous efficiency causes the rate of increase in the optical output to slow so as to approach saturation even when current increases.

Of emitted light, light emitted from the vicinity of a side surface 140b of the ridge portion 114 passes through a shorter path in the phosphor layer 140, and thusly is less absorbed by the phosphor layer 140. Therefore, blue light BL emitted from this peripheral region is relatively strong (the ratio of blue light to longer wavelength light is high). Meanwhile, from the central area (non-peripheral region), the blue light is relatively weak (a lower ratio of blue light to longer wavelength light) because of the longer path length in the phosphor layer 140. Therefore, between the light emitted from the peripheral area and the central area color irregularity exists.

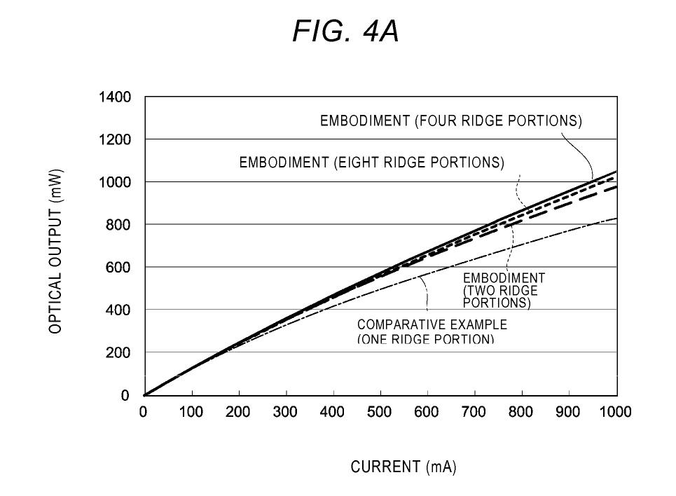

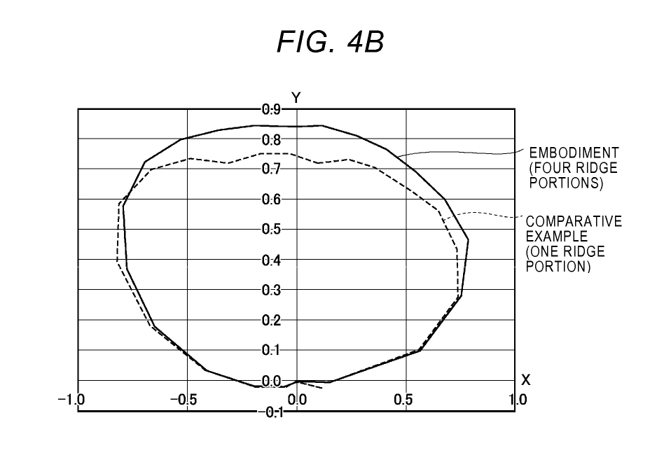

FIG. 4A is a graph illustrating dependence of optical output on current, and FIG. 4B is a graph for comparing light distribution patterns.

In FIG. 4A, the vertical axis represents optical output (mW) and the horizontal axis represents current (mA), and the optical outputs and light distribution patterns of light emitting devices each having a chip size of 1 mm by 1 mm are obtained by simulations.

A case where the number of ridge portions is one is the comparative example, and cases where the number of ridge portions is two, four, or eight are examples of the first embodiment. When the current is 1,000 mA, in the case where the number of ridge portions is two, the optical output is 970 mW, and in the case where the number of ridge portions is four, the optical output is 1,030 mW, and in the case where the number of ridge portions is eight, the optical output is 1,020 mW. In the case where the number of ridge portions is four, the optical output is highest. In contrast to this, in the comparative example in which the number of ridge portions is one, the optical output is 810 mW which is low.

In this manner, as the number of ridge portions increases, the horizontal distance Dh between the center of the light emitting layer 12 and the center of the first electrode 60 is reduced, and it is possible to suppress concentration of carriers while narrowing the width of the area where the carrier density decreases. As a result, the luminous area EL broadens, and carrier overflow and Auger non-radiative recombination are suppressed, and it is possible to keep the luminous efficiency high. Further, the ratio of blue light which is emitted from the side surface 40b of the phosphor layer 40 decreases, and color irregularity decreases.

Further, in a case where the first electrode 60 is set as the n-side electrode, even when a distance from the first electrode 60 up to the light emitting layer 12 is long, it is easy to spread electrons, since electrons have a mobility higher than that of holes, into a wider range of the light emitting layer 12. Furthermore, since the second electrode (the p-side electrode) is provided to widely cover the surfaces of the ridge portions and has a short running distance up to the light emitting layer 12, the second electrode 50 can spread holes having mobility lower than that of electrons, into the light emitting layer 12. Therefore, it is possible to further improve the luminous efficiency.

In FIG. 4B, the light distribution pattern of the first embodiment having four ridge portions is shown by a solid line, and the light distribution pattern of the comparative example having one ridge portion is shown by a dashed line.

The vertical axis Y represents a vertical coordinate relative to a light emitting surface, and the horizontal axis X represents a horizontal coordinate relative to the light emitting surface. The upper portion of the light distribution pattern of the present embodiment is wider than that of the light distribution pattern of the comparative example. In this manner, since optical output directed upward is high, optical output directed to a horizontal direction relatively decreases, and color irregularity may decrease.

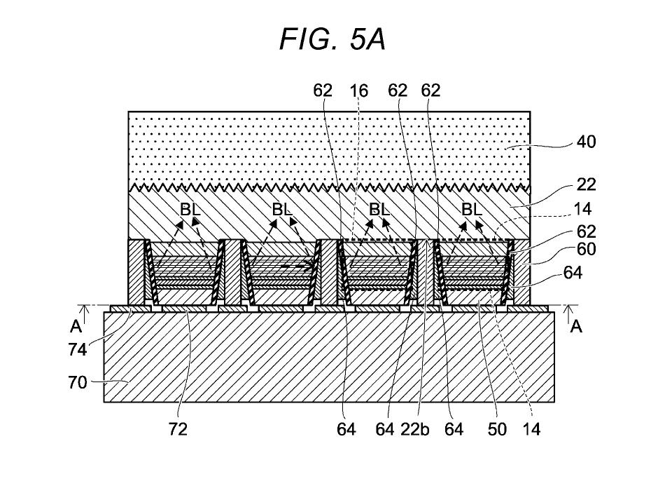

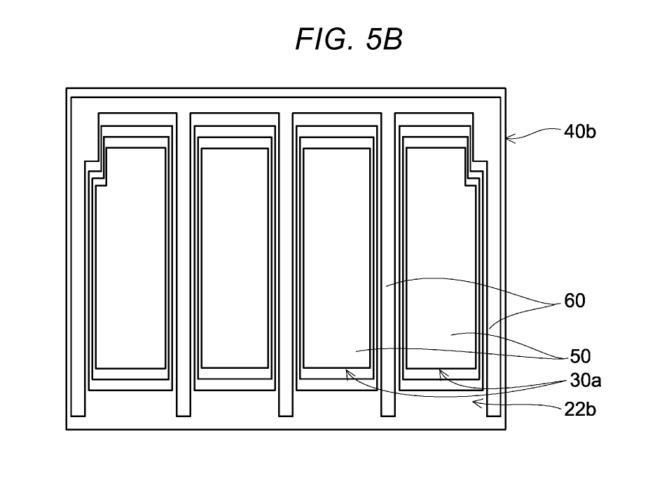

FIG. 5A is a schematic cross-sectional view illustrating a nitride semiconductor light emitting device according to a second embodiment, and FIG. 5B is a schematic plan view illustrating the laminate side as seen along a line A-A of FIG. 5A.

The nitride semiconductor light emitting device includes a laminate 10, a first electrode 60, a second electrode 50, and a phosphor layer 40.

The laminate 10 which is formed of a nitride semiconductor includes a first layer 20 including a first-conductivity type layer 22, a second layer 30 including a second-conductivity type layer, and a light emitting layer 12 provided between the first layer 20 and the second layer 30 and containing a nitride semiconductor. The laminate 10 has at least two ridge portions (first ridge portion 14 and second ridge portion 16) having steps formed from the surface 30a of the second layer 30 opposite to the light emitting layer up to the surface (base surface) 22b of the first-conductivity type layer 22 of the first layer 20.

The nitride semiconductor light emitting device of the second embodiment includes insulating layers 62 provided on the side surfaces of the step portion 14a of the first ridge portion 14 and the side surfaces of the step portion 16a of the second ridge portion 16, and reflective portions 64 provided between the insulating layers 62 and the first electrode 60. Further, the width of the first ridge portion 14 and the width of the second ridge portion 16 increase toward the base surface 22b of the first-conductivity type layer 22.

The reflective portions 64 may be formed of a metal having high reflectance for even a blue light wavelength, such as silver or aluminum. When the base angle α of each ridge portion is set to, for example, about 45 degrees, it is possible to efficiently reflect emitted light BL from the light emitting layer 12 toward the phosphor layer 40.

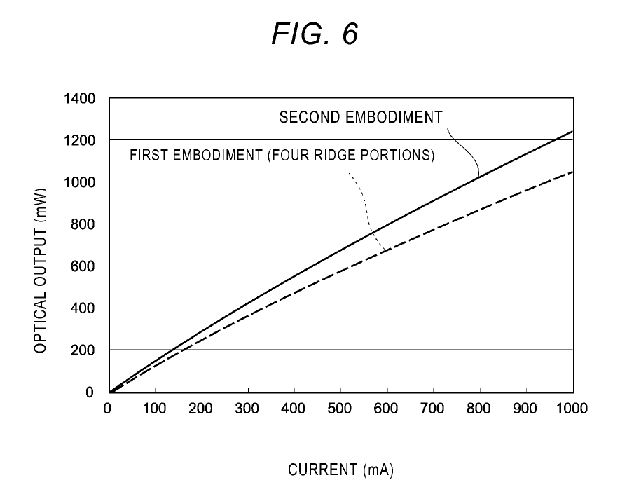

FIG. 6 is a graph chart illustrating the optical output of the nitride semiconductor light emitting device according to the second embodiment.

When the current is 1,000 mA, the optical output (shown by a solid line) of the second embodiment having reflective portions 64 formed on four ridge portions is 1,230 mW. Meanwhile, the optical output of the first embodiment having four ridge portions and the same laminate composition is 1,030 mW. That is, when the reflective portions 64 are formed on the side surfaces of the step portions 14a and 16a of the ridge portions of the laminate 10 whose base angles are 45 degrees, with the insulating layers interposed therebetween, it is possible to further improve the optical output.

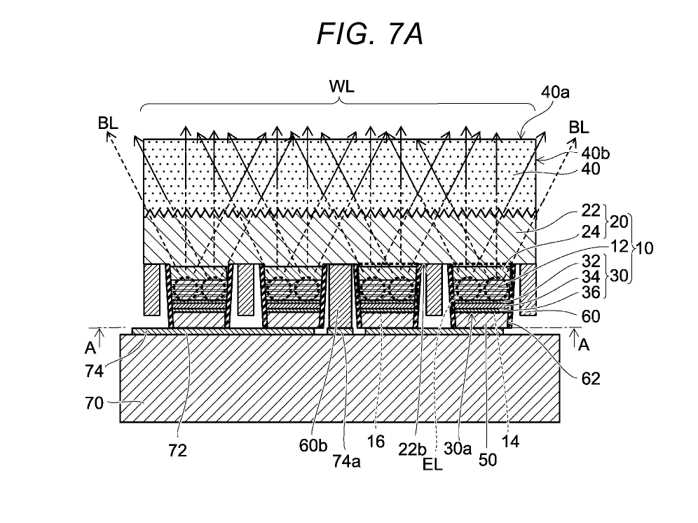

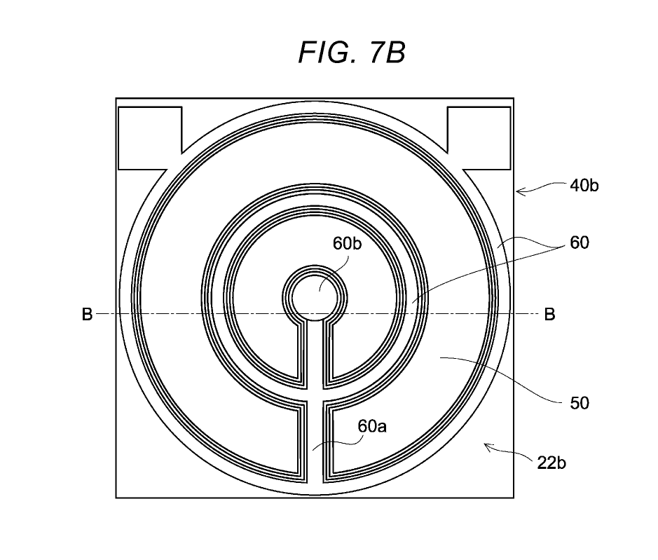

FIG. 7A is a schematic cross-sectional view illustrating a nitride semiconductor light emitting device according to a third embodiment, and FIG. 7B is a schematic plan view illustrating the laminate side as seen along a line A-A of FIG. 7A.

In this third embodiment, each ridge portion may be a portion of a ring shape, such as, for example, depicted in FIG. 7B. In the third embodiment, two ridge portions 14 and 16 are adjacent to each other. Each of the two ring-shaped ridge portions 14 and 16 is partially disconnected (that is, the two ridge portions do not form a fully closed ring, but rather each separately forms a “C”-shaped structure or a partial ring shape), and in the disconnected radial area (the opening in the ring shape), it is possible to provide an area 60a for connecting neighboring portions of the first electrode 60. Further, in a case where each ridge portion has a ring shape, the longitudinal direction of a corresponding step portion may be the direction of the tangent to the ring.

Further, FIG. 7A is a schematic cross-sectional view taken along a line B-B of FIG. 7B. For example, when a first electrode area 60b provided at a central portion of the ring shape is connected to a support-substrate-side first electrode 74a, it is possible to connect the first electrode area 60b to a power supply through the insulating support substrate 70.

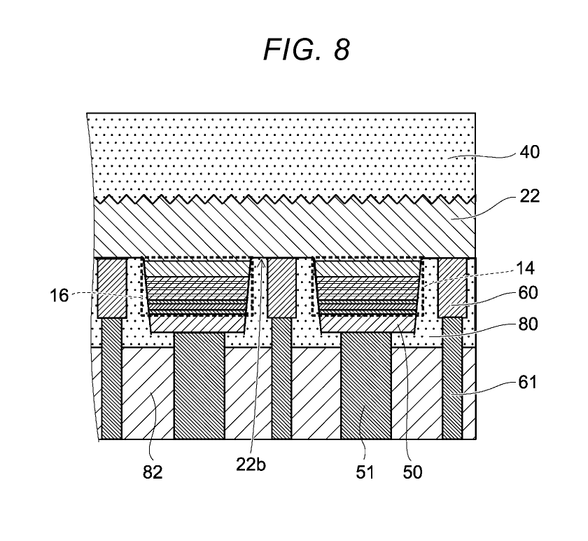

FIG. 8 is a schematic cross-sectional view illustrating a nitride semiconductor light emitting device according to a fourth embodiment.

A laminate 10 and a phosphor layer 40 need not be bonded to an insulating support substrate. In the structure of FIG. 2D, the plurality of ridge portions, the first electrode 60, and the second electrode 50 are covered by an insulating layer 80 or the like. Further, openings are formed to expose the surfaces of the first electrode 60 and the second electrode 50.

Thereafter, for example, a photoresist or the like is used as a mask to form a first pillar electrode 61, which is formed of copper or the like and is connected to the first electrode 60, and a second pillar electrode 51, which is formed of copper or the like and is connected to the second electrode 50, with plating or the like. Next, the photoresist or the like is removed, and a reinforcing resin layer 82 or the like is filled therein.

When the thicknesses of the first pillar electrode 61, the second pillar electrode 51, and the reinforcing resin layer 82 are set to, for example, 50 μm to 300 μm, it is possible to improve mechanical strength. Therefore, it is possible to remove the substrate for crystal growth, and to provide a phosphor layer 40 on the exposed surface of the first-conductivity type layer 22. That is, even when bonding to an insulating supporting substrate is not performed, it is possible to perform packaging at a wafer level. Further, the reinforcing resin layer 82 may have a light blocking property (that is, layer 82 may be opaque or partially opaque to emitted light).

According to the first to fourth embodiments, nitride semiconductor light emitting devices having less color irregularity and higher optical output may be provided. These nitride semiconductor light emitting devices may be widely used in illuminating devices, displays, signals, and so on.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting device, comprising:
a first layer having a first-conductivity type;
a first protrusion disposed on a first side of the first layer and extending from the first layer in a first direction;
a second protrusion disposed on the first side of the first layer and extending from the first layer in the first direction, the second protrusion being spaced from the first protrusion in a second direction perpendicular to the first direction;
a first electrode disposed on the first side of the first layer and between the first and second protrusions;
a phosphor layer disposed on a second side of the first layer that is opposite the first side; and
a second electrode disposed on each of the first and second protrusions on a side opposite the first layer,
the first and second protrusions each including a second layer having a second-conductivity type, and a light emitting layer disposed between the first layer and the second layer.

2. The light emitting device of claim 1, wherein the first and second protrusions each have a rectangular shape when viewed from the first direction.

3. The light emitting device of claim 1, wherein the first and second protrusion each have a partial ring shape when viewed from the first direction.

4. The light emitting device of claim 1, wherein the first electrode has a first portion between the first and second protrusions, a second portion on aside of the first protrusion opposite the first portion, a third portion on a side of the second protrusion opposite the first portion, and a fourth portion connecting the first, second, and third portions.

5. The light emitting device of claim 4, wherein the fourth portion extends in the second direction.

6. The light emitting device of claim 1, wherein the light emitting layer has a multi-quantum well structure.

7. The light emitting device of claim 1, wherein the light emitting layer includes a nitride semiconductor material.

8. The light emitting device of claim 1, wherein an interface between the first layer and the phosphor layer has irregularities for preventing internal reflections.

9. The light emitting device of claim 1, wherein each protrusion includes a portion of the first layer.

10. The light emitting device of claim 1, wherein each protrusion includes a superlattice layer between the light emitting layer and the first layer.

11. The light emitting device of claim 10, wherein each protrusion extends from a level within the first layer.

12. The light emitting device of claim 1, further comprising:
an insulating material disposed on side surfaces of each protrusion such that the insulating material is between each protrusion and the first electrode in the second direction.

13. The light emitting device of claim 12, further comprising:
a reflective material disposed between the insulating material and the first electrode in the second direction, wherein each protrusion has a width in the second direction that decreases with distance in the first direction from a base of the protrusion on the first layer.

14. The light emitting device of claim 1, further comprising:
a connection electrode formed on a supporting substrate that electrically connects the second electrode disposed on the first protrusion with the second electrode disposed on the second protrusion.

15. A nitride semiconductor light emitting device, comprising:
a first layer having a first conductivity type;
first and second protrusions disposed on a first side of the first layer, extending from the first layer in a first direction, and spaced from adjacent protrusions in a second direction perpendicular to the first direction, each protrusion including a second layer having a second-conductivity type and a light emitting layer disposed between the first layer and the second layer;
a first electrode disposed on a first side of the first layer between the protrusions;
a second electrode disposed on a surface of the second layer opposite the light emitting layer; and
a phosphor layer disposed on a second side of the first layer that is opposite the first side.

16. The nitride semiconductor light emitting device of claim 15, wherein each protrusion has a rectangular shape when viewed from the first direction.

17. The nitride semiconductor light emitting device of claim 15, wherein each protrusion has a partial ring shape when viewed from the first direction.

18. The nitride semiconductor light emitting device of claim 15, further comprising:
an insulator material disposed on side surfaces of the protrusions such that the insulator material is between each protrusion and the first electrode in the second direction; and
a reflective material disposed between the insulator material and the first electrode in the second direction.

19. The nitride semiconductor light emitting device of claim 15, further comprising:
a first pillar electrode contacting the second electrode disposed on the first protrusion and extending in the first direction;
a second pillar electrode contacting the second electrode disposed on the second protrusion and extending in the first direction; and
a third pillar electrode between the first and second pillar electrodes, contacting the first electrode, and extending in the first direction.

20. The nitride semiconductor light emitting device of claim 19, further comprising:
a reinforcing resin surrounding the pillar electrodes.
